(19) United States
(12) Patent Application Publication
(10) Pub. No.: US 2001/0013773 A1
(43) Pub. Date: Aug. 16, 2001

(54) Configuration with a plurality of sensor groups and method of determining its intactness

(76) Inventors: Robert Aigner, Munchen (DE); Klaus-Gunter Oppermann, Holzkirchen (DE); Hergen Kapels, Neubiberg (DE)

Correspondence Address: LERNER AND GREENBERG, P.A., Post Office Box 2480, Hollywood, FL, 33022-2480, US

(21) Appl. No.: 09/761,802

(22) Filed: Jan. 16, 2001

Related U.S. Application Data
(63) Continuation of application No. PCT/DE99/02019, filed on Jul. 1, 1999.

(30) Foreign Application Priority Data
Jul. 14, 1998 (DE) 198 31 600.3

(51) Int. Cl. G01R 1/00

(52) U.S. Cl. 324/158.1

(57) ABSTRACT

A method of determining an intactness of a configuration having a plurality of sensor groups, includes the steps of forming, for all of the sensor groups, associated test signals by summing up electric signals of all respective other ones of the sensor groups. All the test signals are compared with one another; and it is selectively determined that an intactness exists, if the test signals are all substantially equal to one another, and it is determined that the intactness does not exist if the test signals are not substantially equal to one another. The configuration is provided such that each sensor group can be disconnected so as to exclude its signal from the aggregate signal. The configuration is preferably provided in a CMOS circuit on a single semiconductor chip.

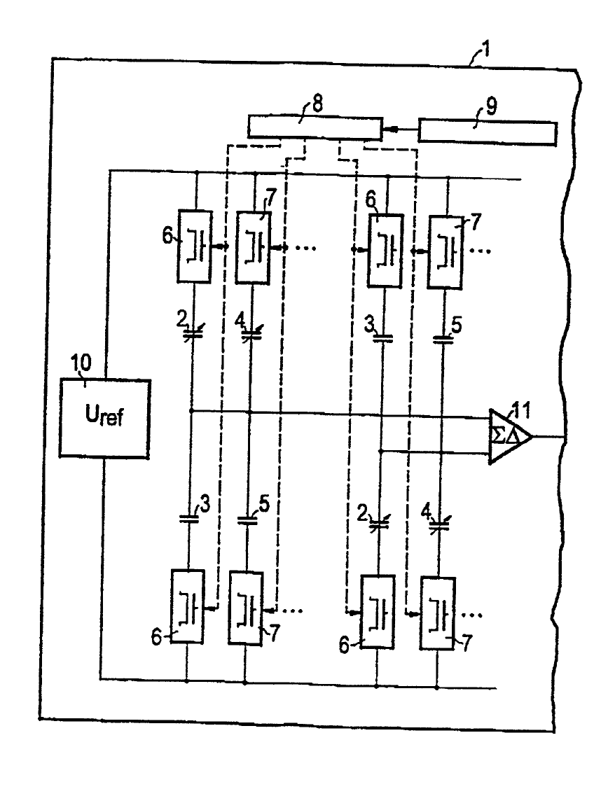

### CROSS-REFERENCE TO RELATED APPLICATION

This application is a continuation of copending International Application No. PCT/DE99/02019, filed Jul. 1, 1999, which designated the United States.

### BACKGROUND OF THE INVENTION

Field of the Invention

The invention relates to a method of determining the intactness of a configuration with a plurality of sensor groups. Each sensor group supplies an electric signal. An evaluation device for the evaluation of a summation signal summated from all the signals is assigned to the plurality of sensor groups. The invention also relates to a configuration having a plurality of sensor groups.

The invention is based on a conventional configuration with a plurality of sensor groups, each of which supplying an electric signal and which are assigned an evaluation device for the evaluation of a summation signal summated from all the signals. The invention thus refers in particular to such a configuration which is implemented on a single semiconductor chip, wherein each sensor of a sensor group is a pressure sensor configured by micromechanical technology. The invention also refers to an electric circuit in which the sensor configuration is embedded and to which it is connected. The electric circuit and the sensors are configured by CMOS (Complimentary Metal Oxide Semiconductor) technology. A semiconductor chip structured in such a way is occasionally referred to as a “CMOS-compatible pressure sensor”, using the word “sensor” in a way not quite in accordance with the choice of words in the present text. (See for example International Publication No. WO 91/12507 in this respect).

A single pressure sensor configured by micromechanical technology contains as an essential element a membrane which has been etched out of a semiconducting solid body which can be deformed under the action of an external pressure and forms a first electrode of a capacitor. Assigned to the membrane is a substantially undeformable second electrode, which, with the first electrode, forms a capacitor which has a capacitance which is variable on the basis of the bending of the membrane and of the first electrode occurring due to external pressure. With the aid of this membrane, the measurement of an external pressure can consequently be gathered from the measurement of a capacitance. According to customary practice, the latter measurement takes place with the aid of a bridge circuit including four capacitances, of which two are invariable capacitances and two are variable capacitances in the form of individual pressure sensors of the type described. A suitable evaluation device, according to customary practice a sigma-delta modulator, is to be connected to this bridge. (See German Patent No. DE 196 25 666 C1)

The capacitance of a single micromechanical pressure sensor of the type described is generally extremely low and accordingly only measurable if a comparatively high measuring error is accepted. Therefore, the use of more or less complex configurations including a large number of measuring bridges of the type described connected in parallel with one another is common. Consequently, the individual capacitances in the measuring bridges add together, so that a summation signal is obtained from the summated signals of the individual bridges and is available for precise measurement through the use of an evaluation device such as a sigma-delta modulator. In such a configuration, the totality of all the sensors or measuring bridges can be subdivided into a greater or lesser plurality of sensor groups.

During the mass production of such a configuration, in particular a CMOS-compatible pressure sensor on a semiconductor chip, checking the finished semiconductor chip for intactness of the individual sensors is of great importance. This is so in particular because the possibility of the presence of a defective membrane on the semiconductor chip compromises its reliability considerably.

It has so far been customary to have the individual sensors on a corresponding semiconductor chip checked visually by an appropriately trained person. In this way, a membrane which has a large crack or is soiled or a membrane clinging to another part of the semiconductor chip can be detected. It is conceivable for the check by a trained person to be replaced by a check through the use of an automatic image processing method. However, it cannot be expected in any case that a relatively small crack or other minor defect of a membrane will be reliably detected. Once such a semiconductor chip has been fitted in a pressure measuring device, there is also generally no possibility of a further visual check.

There is also no realistic prospect of concluding the intactness of individual membranes by cyclically repeated subsequent measurement of a characteristic curve of an entire corresponding semiconductor chip, since characteristic curves of a number of such semiconductor chips that are to be regarded as identical may deviate greatly from one another, even if it is assumed that all the membranes are intact. It is accordingly not possible to prescribe a model characteristic curve for a measurement of this type.

### SUMMARY OF THE INVENTION

It is accordingly an object of the invention to provide a method of determining the intactness of a configuration with a plurality of sensor groups which overcomes the above-mentioned disadvantages of the heretofore-known methods of this general type and which allows a reliable assessment of the intactness of the configuration and can preferably be carried out at any time, in particular after the semiconductor chip has been fitted into a corresponding measuring device.

It is a further object of the invention to provide a corresponding sensor configuration as well as a semiconductor chip including the sensor configuration.

With the foregoing and other objects in view there is provided, in accordance with the invention, a method of determining an intactness of a configuration having a plurality of sensor groups, the method includes the steps of:

providing a configuration having a plurality of sensor groups configured for supplying respective electric signals;

providing an evaluation device assigned to the plurality of sensor groups for evaluating a summation signal summated from all of the electric signals;

forming, for all of the sensor groups, associated test signals by summing up the electric signals of all respective other ones of the sensor groups;

comparing all the test signals with one another; and

selectively determining that an intactness exists, if the test signals are all substantially equal to one another, and determining that the intactness does not exist if the test signals are not substantially equal to one another.

In other words, in order to achieve the object of the invention, there is provided a method of determining the intactness of a configuration with a plurality of sensor groups, through each of which an electric signal can be supplied and which are assigned an evaluation device for the evaluation of a summation signal summated from all the signals, which method includes the following steps:

for each sensor group, forming an associated test signal by summation of signals of all the respective other sensor groups;

comparing of all the test signals with one another; and

determining that an intactness exists if the test signals are all the same as one another, and determining that that the intactness does not exist if the test signals are not all the same as one another.

According to another mode of the invention, each of the sensor groups having a test signal which is different from several other ones of the test signals is determined.

According to yet another mode of the invention, the configuration of the sensor groups, the evaluation device and a switching configuration for forming the test signals are implemented in a circuit on a single semiconductor chip; and the test signals are generated by using switching operations within the circuit.

This method uses, for the measurements required for the determination of intactness, the evaluation device assigned in any case to the configuration for an operation as intended; there is also provision for the formation of test signals which can be processed by this evaluation device meaningfully and with all the necessary precision. For determining the intactness, test signals are formed by in each case excluding from the summation a single sensor group, including an appropriately selected number of individual sensors or measuring bridges. Subsequently, the test signals are compared with one another. If the test signals are all the same as one another, with in this case the terms “the same as one another” or “substantially equal to one another” meaning “the same as one another within an appropriate tolerance” or “substantially equal to one another within an appropriate tolerance”, it can be assumed that all the sensor groups are intact. If there is a sensor group or small number of sensor groups of which the test signal or test signals deviate(s) significantly from other test signals, it can be assumed that this sensor group is defective or these sensor groups are defective. Deviations of the test signals are in this case conceivable both to higher values and to lower values; in the case of sensor groups with pressure sensors of the type described, a membrane affected by a crack will have a distinctly smaller capacitance than an intact membrane and a clinging membrane will have a distinctly higher capacitance than an intact membrane.

In the method, each sensor group of which the associated test signal is different from a number of other test signals is preferably additionally ascertained; in this way, a localization of that sensor group which is to be assessed as not intact takes place.

Also preferred is a method in which the configuration of the sensor groups, the evaluation device and a switching configuration for forming the test signals are realized in a circuit on a single semiconductor chip and in which the test signals are formed by switching operations within the circuit. This embodiment allows the application of the invention for the CMOS-compatible pressure sensor as described above and is based on a comparatively low hardware expenditure in the form of the switching configuration mentioned which is necessary for the method to be realized. This comparatively low expenditure, which can be reduced still further by grouping the individual sensors into an appropriately small number of sensor groups, makes it possible to accommodate a circuit for realizing the method on a single semiconductor chip, with appropriate expansion of the conventional circuit.

With the objects of the invention in view there is also provided, a sensor configuration, including:

a plurality of sensor groups for providing respective electric signals;

an evaluation device assigned to the sensor groups for evaluating a summation signal of a summation of all of the electric signals; and

a switching configuration connected to the sensor groups, the switching configuration switching off each respective one of the sensor groups such that a corresponding one of the electric signals associated with the respective one of the sensor groups is excluded from the summation.

In other words, in order to achieve the object of the invention with respect to the configuration itself, there is specified a configuration with a plurality of sensor groups, through each of which an electric signal can be supplied and which are assigned an evaluation device for the evaluation of a summation signal summated from all the signals, in which configuration a switching configuration with which each sensor group can be switched off to exclude its signal from the summation is also provided.

According to another feature of the invention, the switching configuration includes, for each respective one of the sensor groups, a switch for disconnecting the respective one of the sensor groups from an electrical source voltage.

According to another feature of the invention, each of the sensor groups includes a group of capacitive sensors.

According to another feature of the invention, the evaluation device includes a sigma-delta modulator; and the capacitive sensors are connected in a capacitance measuring bridge.

According to another feature of the invention, each of the capacitive sensors includes at least one pressure-sensitive membrane.

According to another feature of the invention, the sensor groups, the evaluation device, and the switching configuration form a single semiconductor chip circuit.

According to another feature of the invention, the evaluation device and the switching configuration are CMOS devices.

According to another feature of the invention, a memory is connected to the switching configuration, the memory storing information for a permanent state of the switching configuration.

As stated above, the switching configuration preferably includes for each sensor group a switch by which this sensor group can be disconnected from an electrical energy supply.

As mentioned, it is further preferred for each sensor group of the configuration to include a group of capacitive sensors. In this case, it is further preferred for the evaluation device to include a sigma-delta modulator, and for each capacitive sensor to be connected as a capacitance measuring bridge. In addition, it is preferred for each capacitive sensor to include at least one pressure-sensitive membrane.

The configuration is preferably realized in a circuit on a single semiconductor chip, it further being preferred for the evaluation device and the switching configuration to be realized by CMOS technology.

A preferred embodiment of the configuration additionally has a memory in which information for a permanent state of the switching configuration can be stored. This embodiment makes it possible to provide in the configuration, in addition to the sensors or sensor groups absolutely necessary for the intended function, redundant sensor groups which can take over the function of sensor groups that are not intact. The memory preferably provided performs valuable services for this purpose, since the information for the selection of only the intact sensor groups for the operation of the configuration as intended can be stored in this memory.

With the objects of the invention in view there is also provided, a semiconductor device, including:

a semiconductor chip including a plurality of sensor groups for providing respective electric signals; the semiconductor chip including an evaluation device assigned to the sensor groups for evaluating a summation signal of a summation of all of the electric signals; and

the semiconductor chip including a switching configuration connected to the sensor groups, the switching configuration switching off each respective one of the sensor groups such that a corresponding one of the electric signals associated with the respective one of the sensor groups is excluded from the summation.

Other features which are considered as characteristic for the invention are set forth in the appended claims.

Although the invention is illustrated and described herein as embodied in a configuration with a plurality of sensor groups and method of determining its intactness, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

The single FIGURE is a partial, schematic plan view of a configuration according to the invention with a plurality of sensor groups, set up for performing the method according to the invention.

### DESCRIPTION OF THE PREFERRED EMBODIMENTS

Referring now to the single FIGURE of the drawing in detail, there is shown a semiconductor chip 1, on which there is mounted, inter alia, a configuration with a plurality of sensor groups 2, 3, 4, 5. Two sensor groups can be seen, symbolically represented as single capacitance measuring bridges. Depending on the circumstances of the actual individual case, a sensor group may have a plurality or multitude of such measuring bridges, which are connected in parallel with one another. The number of two sensor groups is also not in any way representative of a specific application.

A first sensor group includes two capacitive sensors 2, configured by micromechanics as explained above, and two reference capacitors 3 with invariable capacitance in each case. The reference capacitors 3 are produced by the same technology as the capacitive sensors 2, to eliminate to a great extent malfunctioning caused by manufacture-related imbalances. Similarly produced and configured are capacitive sensors 4 and reference capacitors 5 of a second sensor group.

For measuring an external pressure which acts on the capacitive sensors 2 and 4, the first sensor group and the second sensor group are connected in parallel with each other in order to increase the precision of the measurement. To be able to determine the intactness of the sensor groups while avoiding unnecessary expenditure, a switching configuration 6 7 and 8 is provided, including four switches 6 assigned to the first sensor group, four switches 7 assigned to the second sensor group and a controller 8 for the switches 6 and 7.

With this switching configuration 6, 7 and 8, for the formation of a test signal in which the signal of one of the sensor groups is excluded from a summation of the signals of all the remaining sensor groups, the first sensor group can be optionally switched off by the switches 6 and the second sensor group can be optionally switched off by the switches 7. Consequently, it is possible to generate for each sensor group a test signal which is characterized in that the sensor group concerned is not taken into consideration in the formation of this test signal by summation, unlike in the case of a measuring operation as intended, in which all the sensor groups contribute to a summation signal to be evaluated.

If all the test signals correspondingly obtained are the same as one another, it can be assumed that the capacitive sensors of all the sensor groups are intact. If there are significant differences among the test signals, it can be concluded that at least one sensor group is not intact, and such a sensor group that is not intact can also be ascertained by identifying the test signal deviating from the other test signals.

Not all the sensor groups provided on the semiconductor chip 1 have to be necessary for operation of the semiconductor chip as intended; there may be at least one redundant sensor group, which can functionally replace a not intact sensor group possibly found. Since major parts of the switching configuration are already realized on the semiconductor chip, testing involving determination of the intactness of the sensor groups on the semiconductor chip is possible not just directly after completion of the semiconductor chip but also at virtually any desired later time. At such a later time, a no longer intact sensor group can then be shut down if need be and a still available intact sensor group can instead be activated for the purpose of using the semiconductor chip 1 as intended. For this purpose, the semiconductor chip 1 includes a memory 9, in which appropriate information for the controller 8 can be stored.

In order to use the semiconductor chip as intended, and also for determining the intactness of the sensor groups, the sensor groups are subjected to a reference voltage from a voltage source 10, switching off being performed through the use of the switches 6 or 7 for determining the intactness of individual sensor groups. The summation of the corresponding signals of the capacitive measuring bridges and the evaluation of the summation signal or test signal thus obtained take place by an evaluation device 11, in the present case by a sigma-delta modulator 11. The structure and function of the latter are known in principle and do not require any explanation at this point.

The method according to the invention and the configuration according to the invention make it possible for configurations with sensor groups such as conventional “CMOS-compatible pressure sensors” to undergo both an uncomplicated check during production and a check during operation, which can be repeated as required, and consequently contribute significantly to the expansion of the application of corresponding sensor systems.

We claim:

1. A method of determining an intactness of a configuration having a plurality of sensor groups, the method which comprises:
providing a configuration having a plurality of sensor groups configured for supplying respective electric signals;
providing an evaluation device assigned to the plurality of sensor groups for evaluating a summation signal summated from all of the electric signals;
forming, for all of the sensor groups, associated test signals by summing up the electric signals of all respective other ones of the sensor groups;
comparing all the test signals with one another; and
selectively determining that an intactness exists, if the test signals are all substantially equal to one another, and determining that the intactness does not exist if the test signals are not substantially equal to one another.

2. The method according to claim 1, which comprises determining each of the sensor groups having a test signal which is different from several other ones of the test signals.

3. The method according to claim 1, which comprises:
implementing the configuration of the sensor groups, the evaluation device and a switching configuration for forming the test signals in a circuit on a single semiconductor chip; and
generating the test signals by using switching operations within the circuit.

4. A sensor configuration, comprising:
a plurality of sensor groups for providing respective electric signals;
an evaluation device assigned to said sensor groups for evaluating a summation signal of a summation of all of the electric signals; and
a switching configuration connected to said sensor groups, said switching configuration switching off each respective one of said sensor groups such that a corresponding one of the electric signals associated with said respective one of said sensor groups is excluded from the summation.

5. The configuration according to claim 4, wherein said switching configuration includes, for each respective one of said sensor groups, a switch for disconnecting the respective one of the sensor groups from an electrical source voltage.

6. The configuration according to claim 4, wherein each of said sensor groups includes a group of capacitive sensors.

7. The configuration according to claim 6, wherein:
said evaluation device includes a sigma-delta modulator; and
said capacitive sensors are connected in a capacitance measuring bridge.

8. The configuration according to claim 7, wherein each of said capacitive sensors includes at least one pressure-sensitive membrane.

9. The configuration according to claim 4, wherein said sensor groups, said evaluation device, and said switching configuration form a single semiconductor chip circuit.

10. The configuration according to claim 9, wherein said evaluation device and said switching configuration are CMOS devices.

11. The configuration according to claim 4, including a memory connected to said switching configuration, said memory storing information for a permanent state of said switching configuration.

12. A semiconductor device, comprising:
a semiconductor chip including a plurality of sensor groups for providing respective electric signals;
said semiconductor chip including an evaluation device assigned to said sensor groups for evaluating a summation signal of a summation of all of the electric signals; and
said semiconductor chip including a switching configuration connected to said sensor groups, said switching configuration switching off each respective one of said sensor groups such that a corresponding one of the electric signals associated with said respective one of said sensor groups is excluded from the summation.

13. The semiconductor device according to claim 12, wherein said evaluation device and said switching configuration are CMOS devices.
